(19) United States
(12) Patent Application Publication
(10) Pub. No.: US 2022/0384062 A1
(43) Pub. Date: Dec. 1, 2022

(54) CATHODIC ARC APPLIED RANDOMIZED GRAIN STRUCTURED COATINGS ON ZIRCONIUM ALLOY NUCLEAR FUEL CLADDING

(71) Applicant: Westinghouse Electric Company LLC, Cranberry Township, PA (US)

(72) Inventors: Edward J. LAHODA, Edgewood, PA (US); Benjamin R. MAIER, Pittsburgh, PA (US); Allan W. JAWORSKI, Canonsburg, PA (US); Jonathan WRIGHT, Vasteras (SE); Jorie L. WALTERS, Columbia, SC (US); Robert A. TERRY, Hilton Head Island, SC (US)

(73) Assignee: Westinghouse Electric Company LLC, Cranberry Township, PA (US)

(21) Appl. No.: 17/332,104

(22) Filed: May 27, 2021

(51) Int. Cl. G21C 3/07; C23C 14/32; C23C 14/16; G21C 21/02

(52) U.S. Cl. CPC G21C 3/07; C23C 14/325; C23C 14/16; G21C 21/02

(57) ABSTRACT

The present disclosure is generally related to methods, systems and devices for forming a randomized grain structure coating on a substrate of a component for use in a nuclear reactor to provide protection against corrosion and, more particularly, is directed to improved methods, systems and devices for forming a randomized grain structure coating on a zirconium alloy nuclear fuel cladding tube using a cathodic arc (CA) physical vapor deposition (PVD) process to provide protection against corrosion in both normal operation and in transient and accidents of the nuclear reactor.

### FIELD

The present disclosure is generally related to methods, systems and devices for forming a randomized grain structure coating on a substrate of a component for use in a nuclear reactor to provide protection against corrosion and, more particularly, is directed to improved methods, systems and devices for forming a randomized grain structure coating on a zirconium alloy nuclear fuel cladding tube using a cathodic arc (CA) physical vapor deposition (PVD) process to provide protection against corrosion in both normal operating conditions and in transient and accident conditions of the nuclear reactor.

### SUMMARY

The following summary is provided to facilitate an understanding of some of the innovative features unique to the aspects disclosed herein, and is not intended to be a full description. A full appreciation of the various aspects can be gained by taking the entire specification, claims, and abstract as a whole.

In various aspects, a device, system and method for coating a substrate of a component for use in a nuclear reactor to provide protection against corrosion of the substrate in need thereof are disclosed herein. In an embodiment, the nuclear reactor is a water-cooled nuclear reactor.

In various aspects, a method for applying a randomized grain structure coating on a substrate of a component for use in a nuclear reactor, such as a water-cooled nuclear reactor is disclosed herein.

In various aspects, the method may comprise: providing a substrate; and using a cathodic arc (CA) physical vapor deposition (PVD) process to form on an exterior of the substrate, a protective coating layer with first grains selected from the group consisting of pure Chromium (Cr), a Chromium (Cr) alloy, and combinations thereof. In an embodiment, the protective coating layer may have a randomized grain structure.

In various aspects, the component may be a nuclear fuel rod cladding tube for use in a nuclear reactor, and preferably in a water-cooled nuclear reactor.

In various aspects, the substrate may be a zirconium alloy.

In various aspects, the first grains may have a diameter of about 100 microns or less, or about 50 microns or less.

In various aspects, the first grains may have an average diameter of about 20 microns or less, or preferably about 10 microns or less.

In various aspects, the first grains forming the protective coating layer may be pure Chromium (Cr) grains.

In various aspects, the first grains forming the corrosion resistant layer may be Chromium (Cr) alloy grains.

In various aspects, the Chromium (Cr) alloy grains may comprise one of CrY, FeCrAl, FeCrAlY, CrAlY or CrMo.

In various aspects, the cathodic arc (CA) PVD process comprises: providing a substrate of a Zr alloy tube to be coated; providing a target comprising Cr or Cr alloy to be deposited on the substrate of the Zr alloy tube; supporting the Zr alloy tube and the target of Cr or Cr alloy in a chamber of the CA PVD apparatus; drawing vacuum on the chamber; applying a low voltage between the target comprising the Cr or Cr alloy to be deposited in a thin film on the substrate of the Zr alloy tube and the Zr alloy tube; and utilizing a magnetic field to move the location of the cathodic arc to minimize droplet transfer and obtain even erosion of the target and deposition on the substrate of the Zr alloy tube.

In various aspects, the protective coating layer may have a thickness between about 5 microns and about 150 microns, between about 5 microns and about 100 microns, between about 5 microns and about 50 microns, between about 5 microns and about 20 microns, or between about 5 microns and about 15 microns. In an embodiment, the thickness is between about 5 microns and about 15 microns. In another embodiment, the thickness is about 20 microns.

In various aspects, the method may further comprise polishing or grinding the outer surface of the protective coating layer on the exterior of the substrate to achieve a smoother outer surface.

In various aspects, the method may further comprise first forming on the exterior of the substrate, an intermediate coating layer with second grains with a composition selected from the group consisting of Nb, Mo, Ta, Re, Os, Ru and W, and their alloys, before forming the protective coating layer. The first grains are subsequently applied to the substrate to form the protective coating layer above the intermediate coating layer using the cathodic arc (CA) PVD process. In various aspects, the intermediate coating layer is deposited between the protective coating layer and the exterior surface of the substrate.

In various aspects, the second grains may have a diameter of about 100 microns or less, and an average diameter of about 20 microns or less, or about 10 microns or less.

In various aspects, the intermediate coating layer may be formed by a cathodic arc (CA) physical vapor deposition (PVD) process.

In various aspects, the intermediate coating layer may have a randomized grain structure.

In various aspects, the intermediate coating layer may have a thickness between about 0.5 microns and about 150 microns, between about 0.5 microns and about 100 microns, between about 0.5 microns and about 50 microns, or preferably between about 0.5 microns and about 15 microns.

In various aspects, the intermediate coating layer may prevent eutectic formation between the protective coating layer and the substrate. The thickness of the intermediate coating is minimized to reduce the neutronic penalty while still preventing eutectic formation.

In various aspects, both the intermediate coating layer and the protective coating layer may each have a thickness between about 0.5 microns and about 150 microns, between about 0.5 microns and about 100 microns, between about 0.5 microns and about 50 microns, or between about 0.5 microns and about 15 microns; and the total thickness of the intermediate coating layer and the protective coating layer together is between about 0.5 microns and about 150 microns, between about 1 microns and about 150 microns, between about 1 microns and about 100 microns, between about 1 microns and about 50 microns, or between about 1 microns and about 15 microns. In an embodiment, the total thickness of the two coating layers is about 20 microns.

These and other objects, features, and characteristics of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1 illustrates schematic representation of a grain structure from magnetron sputtering, in accordance with at least one non-limiting aspect of the present disclosure;

FIG. 2 illustrates schematic representation of a randomized grain structure and interface variation from cold spray, in accordance with at least one non-limiting aspect of the present disclosure;

FIG. 3 illustrates schematic representation of a randomized grain structure with no interface variation from a cathodic arc (CA) PVD process, in accordance with at least one non-limiting aspect of the present disclosure; and

FIG. 4 illustrates schematic representation of Nb, Mo, Ta, Re, Os, Ru, or W or alloys of these metals as an intermediate coating layer between Cr or Cr Alloy coating and the Zr alloy tube material, in accordance with at least one non-limiting aspect of the present disclosure.

Corresponding reference characters indicate corresponding parts throughout the several views. The exemplifications set out herein illustrate various aspects of the invention, in one form, and such exemplifications are not to be construed as limiting the scope of the invention in any manner.

### DETAILED DESCRIPTION

Numerous specific details are set forth to provide a thorough understanding of the overall structure, function, manufacture, and use of the aspects as described in the disclosure and illustrated in the accompanying drawings. Well-known operations, components, and elements have not been described in detail so as not to obscure the aspects described in the specification. The reader will understand that the aspects described and illustrated herein are non-limiting examples, and thus it can be appreciated that the specific structural and functional details disclosed herein may be representative and illustrative. Variations and changes thereto may be made without departing from the scope of the claims.

Before explaining various aspects of the articulated manipulator in detail, it should be noted that the illustrative examples are not limited in application or use to the details of disclosed in the accompanying drawings and description. It shall be appreciated that the illustrative examples may be implemented or incorporated in other aspects, variations, and modifications, and may be practiced or carried out in various ways. Further, unless otherwise indicated, the terms and expressions employed herein have been chosen for the purpose of describing the illustrative examples for the convenience of the reader and are not for the purpose of limitation thereof.

In a typical nuclear water reactor, such as a pressurized water reactor (PWR), heavy water reactor (e.g., a CANDU) or a boiling water reactor (BWR), the reactor core includes a large number of fuel assemblies, each of which is composed of a plurality of elongated fuel elements or fuel rods. Fuel assemblies vary in size and design depending on the desired size of the core and the size of the reactor. The fuel rods each contain nuclear fuel fissile material, such as at least one of uranium dioxide (U0₂), plutonium dioxide (Pu0₂), thorium dioxide (Th0₂), uranium nitride (UN) and uranium silicide (U₃Si₂) and mixtures thereof. At least a portion of the fuel rods can also include neutron absorbing material, such as, boron or boron compounds, gadolinium or gadolinium compounds, erbium or erbium compounds and the like. The neutron absorbing material may be present on or in pellets in the form of a stack of nuclear fuel pellets. Annular or particle forms of fuel also can be used.

Each of the fuel rods has a cladding that acts as containment to hold the fissile material. The fuel rods are grouped together in an array which is organized to provide a neutron flux in the core sufficient to support a high rate of nuclear fission and thus, the release of a large amount of energy in the form of heat. A coolant, such as water, is pumped through the reactor core to extract the heat generated in the reactor core to produce useful work such as electricity.

The cladding on the fuel rods may be composed of zirconium (Zr) and may include as much as about two percent by weight of other metals, such as niobium (Nb), tin (Sn), iron (Fe) and chromium (Cr).

The exposure of zirconium cladding to the high-temperature (200° C. to 350° C.) and high pressure water environment in a nuclear reactor during normal operation results in the corrosion (oxidation) of the surface and consequent hydriding (due to the hydrogen release into the metal from the oxidation reaction with water) of the bulk cladding, ultimately leading to metal embrittlement. This weakening of the metal can adversely affect the performance, lifetime, and safety margin of the nuclear fuel core. During transients and accidents, zirconium alloys rapidly react with steam at temperatures of 1100° C. and above to form zirconium oxide and hydrogen. In the environment of a nuclear reactor, the hydrogen produced from that reaction would dramatically pressurize the reactor and would eventually leak into the containment or reactor building leading to potentially explosive atmospheres and to potential hydrogen detonations, which could lead to fission product dispersion outside of the containment building. Maintaining the fission product boundary is of critical importance.

Lahoda et al. in WO 2015/175035 (the '035 Publication) discloses a chemical vapor infiltration (CVI) or chemical vapor deposition (CVD) process to deposit a SiC material to zirconium alloy nuclear fuel cladding tubes to improve the capability for the zirconium alloy cladding to withstand normal and accident conditions to which it is exposed in the nuclear water reactor. The '035 Publication is incorporated by reference herein in its entirety for all purposes, to the extent that the incorporated materials are not inconsistent herewith.

Mazzoccoli et al. in U.S. Pat. No. 10,290,383 (“the '383 Patent”) discloses a method of forming a coating of integrated protective ceramic particles into the zirconium cladding for nuclear reactors by high-velocity thermal application using a hybrid thermal-kinetic deposition or cold thermal spray apparatus. The '383 Patent is incorporated by reference herein in its entirety for all purposes, to the extent that the incorporated materials are not inconsistent herewith.

Lahoda et al. in U.S. Patent Application Publication No. 2020/0051702 (“the '702 Application”) discloses a method for depositing coatings by cold spray. The '702 Application is incorporated by reference herein in its entirety for all purposes, to the extent that the incorporated materials are not inconsistent herewith.

Lahoda et al. in U.S. Patent Application Publication No. 2018/0096743 (“the '743 Application”) discloses a cold spray method for depositing duplex accident tolerant coating for nuclear fuel rods. The '743 Application is incorporated by reference herein in its entirety for all purposes, to the extent that the incorporated materials are not inconsistent herewith.

Chromium (Cr) coatings have recently been demonstrated to provide protection to zirconium (Zr) alloy nuclear fuel cladding tubes against excessive corrosion in both normal operation and in transients and accidents where the temperature of the cladding can exceed 900° C. for a short period of time. The Cr coatings need to be thin (about 5 to about 15 microns) to reduce parasitic neutron absorption.

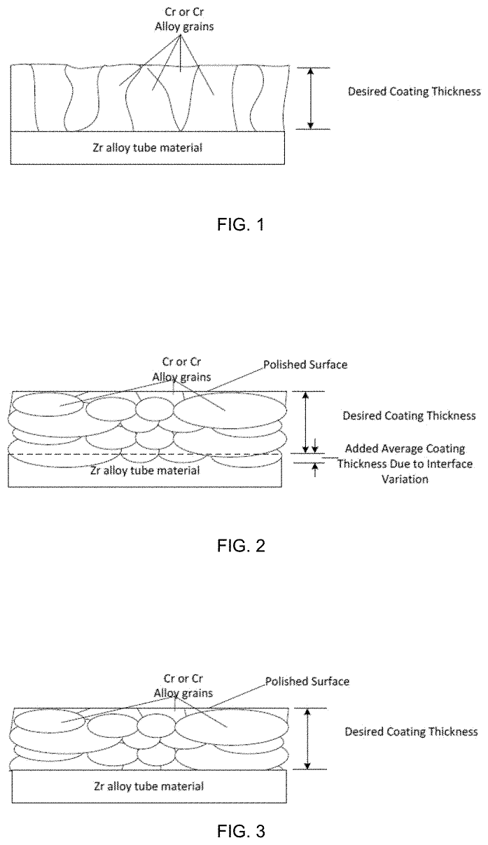

Physical vapor deposition (PVD) has been found to provide good coatings with the appropriate control over the product. Magnetron sputtering (MS) has been used and while providing a good, adherent coating to begin with, the large columnar grain structure (FIG. 1) may provide relatively direct vertical pathways for coolant to reach the Zr alloy-Cr coating interface which can cause zirconium (Zr) corrosion under the Cr coating resulting in delamination of the Cr coating. In addition, this grain structure may also increase the tendency for cracks to propagate from the coating into the underlying zirconium alloy tube due to the vertical orientation of the grain boundaries perpendicular to the zirconium tube surface. Another PVD method is high-power impulse magnetron sputtering (HiPIMS) which deposits a randomized grain structure. Unfortunately, HiPIMS also is a higher cost method for depositing a coating. This is because the process is interrupted to reverse the polarity of the electrodes so that material can be redeposited from the gas. It therefore has a lower deposition rate as well as higher costs for more complex equipment.

Another method for depositing coatings to the zirconium (Zr) alloy nuclear fuel cladding tubes is cold spray. In this process particles are accelerated in a stream of gas towards the tube surface to be coated. These particles impact and deform onto the surface to form randomized grain structure coatings. However, this method also produces a large variation in the interface between the coating and the tube (FIG. 2) due to the high particle momentum which increases the average coating thickness required to achieve the minimum required thickness. It also produces a very rough surface though this is easily remedied using grinding or polishing though at some additional cost.

What is required is a process that produces randomized grain structure while at the same time producing a smooth interface between the coating and the underlying zirconium tube surface.

The present disclosure provides herein a method for applying a randomized grain structure coating on a substrate of a component for use in a nuclear reactor, such as zirconium (Zr) alloy substrate of nuclear fuel cladding tubes for use in a water cooled nuclear reactor, using a cathodic arc (CA) physical vapor deposition (PVD) process.

The cathodic arc (CA) physical vapor deposition (PVD) process deposits a randomized grain structure at very high deposition rates like that of cold spray. At the same time, since it deposits very small molten grains/particles or small collections of atoms, the interface between the coating and the zirconium tube shows little variation (FIG. 3). The cathodic arc (CA) physical vapor deposition (PVD) process produces a somewhat rougher surface than MS PVD but less so than cold spray and this roughness can be remedied by light polishing. The cathodic arc (CA) physical vapor deposition (PVD) process therefore satisfies the requirement for a randomized grain structure and smooth coating-tube interface while at the same time reducing the cost of the deposited coating.

The randomized grains of the CA PVD coating resist easy infiltration of the coolant to the Zr—Cr coating interface, thus reducing the chance for coating delamination due to undercutting corrosion at the interface. These randomized grains also inhibit crack propagation through the coating into the underlying zirconium tube.

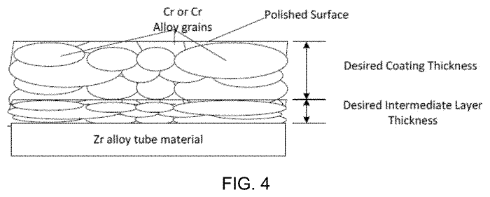

This invention can be applied to Cr and Cr alloys such as those containing Y or Mo as well as other material coatings that can be used to underlay the Cr or Cr alloy coating in an intermediate layer such as Nb, Mo, Ta, Re, Os, Ru, or W or alloys of these metals which may be applied to provide resistance to Cr—Zr eutectic formation (FIG. 4).

While MS PVD (by other PVD vendors) and HiPIMS PVD (by Framatome) are used for coating zirconium tubes, the present inventors are the first to use a cathodic arc (CA) PVD process to apply a randomized grain structure coating on the zirconium nuclear fuel cladding tubes to achieve improved corrosion resistance of these tubes at both normal operation conditions and transients and accidents conditions where the temperature of the cladding can exceed 900° C. for a short period of time.

The present disclosure provides a method for applying a randomized grain structure coating on the zirconium substrate of the nuclear fuel cladding tubes using the cathodic arc (CA) PVD process for improving the corrosion resistance of nuclear fuel cladding tubes at both normal operation conditions and transients and accidents conditions.

In various aspects, the method comprises: providing a substrate; and using a cathodic arc (CA) physical vapor deposition (PVD) process to form on an exterior of the substrate, a protecting coating layer with first grains selected from the group consisting of pure Chromium (Cr), a Chromium (Cr) alloy, and combinations thereof. In an embodiment, the protective coating layer has a randomized grain structure.

As used herein, the term “pure Cr”, or “pure chromium”, means 100% metallic chromium that may include trace amounts of unintended impurities that do not serve any metallurgical function. For example, pure Cr may contain a few ppm of oxygen. The term “Cr-alloy,” “chromium alloy,” “Cr-based alloy,” or “chromium-based alloy” as used herein refers to alloys with Cr as the dominant or majority element together with small but reasonable amounts of other elements that serve a specific function. The Cr alloy may comprise 80% to 99 atom % of chromium. Other element in the Cr alloy may include at least one chemical element selected from silicon, yttrium, aluminum, titanium, niobium, molybdenum, zirconium, and other transition metal elements. Such elements may be present for example at a content of 0.1 atomic % to 20 atomic %.

In various aspects of the method, the grains used for the protective coating layer may be pure metallic chromium grains or chromium (Cr) alloy particles, both of which may have an average diameter of about 20 microns or less, or about 10 microns or less. By “average diameter,” as used herein, those skilled in the art will recognize that the grains may be both spherical and non-spherical so that the “diameter” will be the longest dimension of the regularly or irregularly shaped grains, and the average diameter means that there will be some variation in the longest dimension of any given grain above or below about 20 microns, but the average of the longest dimension of all grains used in the coating are together, about 20 microns or less. Further, the first grains may have a diameter of about 100 microns or less.

When the protective coating layer grains are chromium-based alloys, they may comprise about 80 to 99.9 atom % of chromium. In various aspects, the chromium-based alloy may include at least one element selected from the group consisting of silicon, yttrium, aluminum, titanium, niobium, zirconium, molybdenum and transition metal elements, at a combined content of about 0.1 to 20 atom %. In various aspects, the Cr alloy may be, for example, one of CrY, CrAlY, CrMo, FeCrAlY or FeCrAl.

In various aspects of the method, the substrate is preferably a zirconium alloy and the component, in various aspects, may be a cladding tube for a nuclear fuel rod. The substrate may be any shape associated with the component to be coated. For example, the substrate may be cylindrical in shape, curved, or may be flat. In a nuclear fuel rod, the substrate is preferably cylindrical. In an embodiment, the substrate may be a zirconium alloy, and the component may be a nuclear fuel rod cladding tube for use in a water-cooled nuclear reactor.

In various aspects of the method, the cathodic arc (CA) PVD process involves a source material and a substrate to be coated placed in an evacuated deposition chamber. The chamber contains only a relatively small amount of gas. The negative lead of a direct current (DC) power supply is attached to the source material (the “cathode”) and the positive lead is attached to an anode. In many cases, the positive lead is attached to the deposition chamber, thereby making the chamber the anode. The electric arc is used to vaporize material from the cathode target. The vaporized material then condenses on the substrate, forming the desired layer. The CA PVD process is relatively inexpensive to construct and use and uses robust equipment that requires only limited amounts of maintenance.

In various aspects of the method, the cathodic arc (CA) PVD process comprises: providing a substrate of a Zr alloy tube to be coated; providing a target comprising Cr or Cr alloy to be deposited on the substrate of the Zr alloy tube; supporting the Zr alloy tube and the target of Cr or Cr alloy in a chamber of the CA PVD apparatus; drawing vacuum on the chamber; applying a low voltage between the target comprising the Cr or Cr alloy to be deposited in a thin film on the substrate of the Zr alloy tube and the Zr alloy tube; and utilizing a magnetic field to move the location of the cathodic arc to minimize droplet transfer and obtain even erosion of the target and deposition on the substrate of the Zr alloy tube.

The protective Cr coating layer is applied to the nuclear fuel rod cladding tubes to provide more corrosion protection during normal operation at 280 to 320° C. as well as protection during a design basis accident such as a loss of coolant accident (LOCA). The Zr ignites around 1100° C. while the Cr coated cladding does not start to take off until about 1400° C. and thus the protective Cr coating layer can help gain some reaction time for the plant operators to respond. The protective coating vastly reduces the amount of hydrogen produced throughout the course of an accident thus reducing pressurization of the reactor and the potential for hydrogen explosions when the pressure is released to the containment.

The protective coating layer may have a desired thickness, for example, between about 5 and about 100 microns, but greater thicknesses of, for example, several hundred microns such as from 100 to 150 microns, may be deposited on the exterior surface of the substrate. The protective coating layer should be thick enough to form a protective barrier on the substrate against corrosion, and at the same time be thin enough to reduce parasitic neutron absorption. The protective coating layer reduces, and in various aspects may eliminate, any steam zirconium and air zirconium reactions, and reduces, and in various aspects eliminates, zirconium hydride formation at temperatures of about 1000° C. and above.

In various aspects of the method, the protective coating layer may be ground and polished lightly to reach a smooth outer surface.

In various aspects, the method may further comprise first forming on the exterior of the substrate, an intermediate coating layer with second grains selected from the group consisting of Nb, Mo, Ta, Re, Os, Ru and W, and their alloys, before forming the protective coating layer.

The second grains may have a diameter of about 100 microns or less, and an average diameter of about 20 microns or less.

In various aspect of the method, the intermediate coating layer may be deposited first on the exterior surface of the substrate using a cathodic arc (CA) physical vapor deposition (PVD) process. The intermediate coating layer may have a randomized grain structure. The intermediate coating layer is between the protective coating layer and the exterior of the substrate. The intermediate coating layer may be ground and polished lightly before deposition of the protective coating layer, which may be ground and polished lightly thereafter.

In various aspect of the method, the intermediate coating layer may have a desired thickness between about 0.5 microns and about 100 microns, between about 0.5 microns and about 50 microns, or preferably between about 0.5 microns and about 15 microns, but greater thicknesses of, for example, several hundred microns such as from 100 to 150 microns, may be deposited on the exterior surface of the substrate.

In various aspect of the method, the intermediate coating layer may prevent eutectic formation between the protective coating layer and the substrate.

As described herein above, the protective coating layer acts as a corrosion protective barrier for the substrate. When the substrate is a zirconium alloy cladding, the chromium coating provides a protective barrier against corrosion at normal operating conditions, for example, between 270° C. and 350° C. in pressurized water reactors and between 200° C. and 300° C. in boiling water reactors. The protective coating layer reduces the steam zirconium and air zirconium reactions and hydrogen generation at high temperatures, i.e., those greater than 1100° C.

The intermediate coating layer may be optionally deposited on the exterior surface of the substrate first using a cathodic arc (CA) physical vapor deposition (PVD) process before deposition of the protective coating layer. The intermediate coating layer may mitigate eutectic formation between the protective coating layer and the substrate that limits the performance of the protective coating layer at temperature higher than, for example, 900° C., for Zr or Zr alloy substrate and Cr or Cr alloy coating materials, such as CrY, CrAlY, FeCrAl or FeCrAlY, and thus may further improve the accident tolerance of this embodiment of a protective coating layer at temperatures higher than 900° C.

In general, the intermediate coating material may be chosen from those materials having a eutectic melting point with the zirconium or zirconium alloys that is above 1400° C. and thermal expansion coefficients and elastic modulus coefficients compatible with the zirconium or zirconium alloy substrate on which it is coated and the protective coating layer which is deposited on it. The grains used to form the intermediate coating layer may be Nb, Mo, Ta, Re, Os, Ru and W, or the alloys thereof, all of which form eutectics with Zr or Zr alloys greater than 1400° C., and in various aspects, greater than 1500° C. In certain aspects, the grains used to form the intermediate coating layer may be Mo.

In various aspects of the method, the nuclear fuel rod cladding tube may have two coating layers, a protective coating layer of pure Cr or a Cr alloy (the first grains) and an intermediate coating layer of grains of Nb, Mo, Ta, Re, Os, Ru and W, or the alloys thereof (the second grains). Both coating layers may be applied to zirconium alloy tubes to reduce the reaction of zirconium with steam or air at both normal operating conditions and accident conditions. The two coating layers may be applied using the cathodic arc (CA) physical vapor deposition (PVD) process in sequence, as described above. Each of two coating layers thus has a desired randomized grain structure and has a coating thickness of from about 0.5 to about 150 microns, from about 0.5 to about 100 microns, from about 0.5 to about 50 microns, or from about 0.5 to about 15 microns. The total thickness of the two coating layers together is from about 0.5 to about 150 microns, from about 0.5 to about 100 microns, from about 0.5 to about 50 microns, from about 0.5 to about 15 microns, or from about 1.0 to about 15 microns. The grains in the first and the second layers each have a size of preferably less than about 2.0 microns average diameter but up to about 10.0 microns in diameter.

As explained above, the double coating layers of the present method may further improve the accident tolerance of the coated zirconium alloy cladding by avoidance of eutectic formation between the protective coating layer and the zirconium alloy substrate at eutectic temperatures. The exact temperature will vary depending on the materials used for the substrate and the protective coating layer. Eutectic phase diagrams for determining the eutectic point are readily available in the literature.

In various aspects, following formation of the intermediate coating layer and the protective coating layer, the method may further include annealing the coating. Annealing may impart ductility and may create sub-micron sized grains that, it is believed, will be beneficial for isotropy in properties and resistance to radiation damage. Annealing involves heating the coating in the temperature range of 200° C. to 800° C., and preferably between 350° C. to 550° C. It relieves the stresses in the coating and imparts ductility to the coating which is necessary to sustain internal pressure in the cladding. As the tube bulges, the coating should also be able to bulge.

The method described herein provides in various aspects, a cladding tube formed from a zirconium alloy substrate and having an intermediate coating layer and a protective coating layer formed from chromium or a chromium alloy. In general, the intermediate coating material may be chosen from those materials having a eutectic melting point with the zirconium or zirconium alloys that is in various aspects, above 1400° C., and preferably in certain aspects, above 1500° C., and may in addition, be chosen from those materials having thermal expansion coefficients and elastic modulus coefficients compatible with the zirconium or zirconium alloy substrate on which it is coated and the protective coating layer which is applied above it. Examples include transition metals such as Nb, Mo, Ta, Re, Os, Ru and W, or the alloys thereof that have a high melting point (greater than 1700° C.) and do not form a eutectic or metals that do form a eutectic but at higher temperatures (greater than 1400° C.) than the eutectic that may be formed between the zirconium alloy tube and the protective coating layer formed from chromium or a chromium alloy (around 1333° C.).

The substrate with the two coating layers may also be ground, buffed, polished, or treated preferably lightly by other known techniques to achieve a smoother surface finish.

The method of using the cathodic arc (CA) PVD to coat nuclear fuel rod cladding tubes of the present disclosure offers advantages in the coating grain structure over the use of MS PVD as well as a lower cost than HiPIMS.

All patents, patent applications, publications, or other disclosure material mentioned herein and/or listed in any Application Data Sheet, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present invention has been described with reference to various exemplary and illustrative aspects. The aspects described herein are understood as providing illustrative features of varying detail of various aspects of the disclosed invention; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed invention. Accordingly, it will be recognized by persons having ordinary skill in the art that various substitutions, modifications or combinations of any of the exemplary aspects may be made without departing from the scope of the invention. In addition, persons skilled in the art will recognize, or be able to ascertain using no more than routine experimentation, many equivalents to the various aspects of the invention described herein upon review of this specification. Thus, the invention is not limited by the description of the various aspects, but rather by the claims.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

As used herein, the singular form of “a”, “an”, and “the” include the plural references unless the context clearly dictates otherwise.

Directional phrases used herein, such as, for example and without limitation, top, bottom, left, right, lower, upper, front, back, above, under, and variations thereof, shall relate to the orientation of the elements shown in the accompanying drawing and are not limiting upon the claims unless otherwise expressly stated.

The terms “micron”, “microns” “micrometer” or “μm” as used in the present disclosure means an SI derived unit of length equaling 1×10⁻⁶ meter.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

1. A method for applying a coating on a substrate of a component for use in a nuclear reactor, the method comprising:
providing the substrate of the component to be coated; and
using a cathodic arc (CA) physical vapor deposition (PVD) process to form on an exterior of the substrate, a protecting coating layer with first grains selected from the group consisting of pure metallic Chromium (Cr), a Chromium (Cr) alloy, and combinations thereof,
wherein the protective coating layer has a randomized grain structure in which grain orientation, grain size and grain shape are randomized,
wherein the CA PVD process comprises:
providing a target comprising the first grains to be deposited on the substrate; and
utilizing a magnetic field to move a location of a cathodic arc of a CA PVD apparatus to minimize droplet transfer, and obtain an even erosion of the target and an even deposition on the substrate.

2. The method of claim 1, wherein the substrate is a nuclear fuel rod cladding tube for use in a water-cooled nuclear reactor.

3. The method of claim 1, wherein the substrate is a zirconium alloy.

4. The method of claim 1, wherein the first grains have a diameter of no greater than about 10.0 microns.

5. The method of claim 1, wherein the first grains have an average diameter of no greater than about 2.0 microns.

6. The method of claim 1, wherein the first grains forming the protective coating layer are pure chromium (Cr) grains.

7. The method of claim 1, wherein the first grains forming the protective coating layer are Chromium (Cr) alloy grains.

8. The method of claim 7, wherein the Chromium (Cr) alloy grains comprises one of CrY, CrAlY, FeCrAl or FeCrAlY grains.

9. The method of claim 1, wherein the CA PVD process comprises:
supporting the component and the target in a chamber of the CA PVD apparatus;
drawing vacuum on the chamber; and
applying a voltage between the target and the component.

10. The method of claim 1, wherein the protective coating layer has a thickness between about 5 microns and about 100 microns.

11. The method of claim 1, further comprising polishing an outer surface of the protective coating layer on the exterior of the substrate.

12. The method of claim 1, further comprising first forming on the exterior of the substrate, an intermediate coating layer with second grains selected from the group consisting of Nb, Mo, Ta, Re, Os, Ru and W, and their alloys, before forming the protective coating layer,
wherein the intermediate coating layer is between the protective coating layer and the exterior of the substrate.

13. The method of claim 12, wherein the second grains have a diameter of no greater than 10.0 microns and an average diameter of no greater than about 2.0 microns.

14. The method of claim 12, wherein the CA PVD process is a first CA PVD process, and wherein the intermediate coating layer is formed by a second CA PVD process.

15. The method of claim 12, wherein the intermediate coating layer has a randomized grain structure in grain orientation, grain size and grain shape.

16. The method of claim 12, wherein the intermediate coating layer has a thickness between about 0.5 microns and about 100 microns.

17. The method of claim 12, wherein the intermediate coating layer has a thickness between about 0.5 microns and about 15 microns.

18. The method of claim 12, wherein the intermediate coating layer prevents eutectic formation between the protective coating layer and the substrate.

19. The method of claim 12, wherein a total thickness of the intermediate coating layer and the protective coating layer together is between about 5 microns and about 50 microns.

20. The method of claim 12, wherein the second grains are Mo grains.

21. The method of claim 8, wherein the Chromium (Cr) alloy grains comprises one of FeCrAl or FeCrAlY grains.
